(19) United States
(12) Patent Application Publication
(10) Pub. No.: US 2020/0041354 A1
(43) Pub. Date: Feb. 6, 2020

(54) ELECTRONIC DEVICE

(71) Applicant: SHARP KABUSHIKI KAISHA, Sakai City, Osaka (JP)

(72) Inventor: TOMOYA IDE, Sakai City, Osaka (JP)

(73) Assignee: SHARP KABUSHIKI KAISHA, Sakai City, Osaka (JP)

(21) Appl. No.: 16/499,632

(22) PCT Filed: Mar. 20, 2018
(86) PCT No.: PCT/JP2018/011122

§ 371 Date: Sep. 30, 2019

(30) Foreign Application Priority Data
Apr. 3, 2017 (JP) 2017-073738

(51) Int. Cl. G01K 1/16; H05K 1/14; H05K 7/20; H05K 1/18; H05K 5/00; G01K 7/22

(52) U.S. Cl. CPC G01K 1/16; H05K 1/147; H05K 7/20963; H05K 1/189; H04M 1/026; G01K 7/22; H05K 2201/10151; H04M 2250/12; H05K 5/0017

(57) ABSTRACT

A thermistor is disposed on a thermistor board, and a temperature of a desirable location is measured with a high accuracy. The thermistor that measures a temperature of an inside of a housing of an electronic device is included, and the thermistor is disposed on a thermistor board which is a member different from a board on which the electronic components are disposed or a component on which the electronic components are disposed.

### TECHNICAL FIELD

The present invention relates to an electronic device.

### BACKGROUND ART

Recently, with regard to an electronic device, particularly a small and thin electronic device typified by a smartphone, there has been a growing concern that a temperature of a surface of a housing of the electronic device increases during use and the like with improvement in performance. In order to solve the concern, a technology is researched and developed in which a temperature sensor such as a thermistor is disposed in the housing of the electronic device, the temperature of the surface of the housing is estimated by a temperature measurement of the temperature sensor, and thereby, the temperature of surface of the housing is controlled.

For example, PTL 1 discloses a technology in which a processor disposed on a board in an electronic apparatus acquires a first measurement value from a temperature sensor disposed on the board, and a temperature of a surface of a housing is calculated based on a transfer function G(s) and a transfer function H(s) between a heat source on the board and the surface of the housing in the electronic apparatus, and the first measurement value.

### CITATION LIST

### Patent Literature

PTL 1: Japanese Unexamined Patent Application Publication No. 2016-121985 (published on Jul. 7, 2016)

### SUMMARY OF INVENTION

### Technical Problem

However, the electronic apparatus disclosed in PTL 1 has a structure in which the processor disposed on the board serves as the heat source. That is, the technology disclosed in PTL 1 relates to a method for estimating the temperature of the surface of the housing based on the temperature of the board on which the processor is disposed, and in a case where a plurality of configuration components are arranged in a complicated manner in the housing, the above-described transfer functions G(s) and H(s) are hard to be obtained, and a case is likely to occur in which a correlation between the temperature of the board on which the processor is disposed and the temperature of the surface of the housing may not be accurately obtained. Therefore, there is a possibility that the temperature of the surface of the housing may not be calculated with a high accuracy.

One aspect of the present invention is made in view of the above-described problem, and an object thereof is to measure a temperature of a desirable location on a surface of a housing in an electronic device (electronic apparatus) with a high accuracy regardless of the number of desirable locations.

### Solution to Problem

In order to solve the above-described problem, an electronic device according to one aspect of the present invention is an electronic device in which an electronic component capable of being a heat source depending on a usage mode is disposed on a board or on a component other than the electronic component in a housing, and includes a thermistor that measures a temperature of an inside of the housing, in which the thermistor is disposed on a thermistor board that is a member different from the board or the component on which the electronic component is disposed.

### Advantageous Effects of Invention

According to one aspect of the present invention, by disposing at least one thermistor on a thermistor board, it is possible to measure a temperature of a desirable location on a surface of a housing of the electronic device with a high accuracy regardless of the number of the desirable locations.

### BRIEF DESCRIPTION OF DRAWINGS

FIG. 1 is a schematic diagram illustrating a positional relationship between a desirable measurement location on a surface of a housing and a thermistor in a smartphone according to Embodiment 1 of the present invention.

FIG. 2 is a schematic diagram illustrating another example of a temperature distribution inside the housing.

FIG. 3 is a flowchart illustrating an example of a method of determining the disposition location of the thermistor.

FIG. 4 is a schematic diagram illustrating an internal structure of a housing in a smartphone according to Embodiment 2 of the present invention.

FIG. 5 is a schematic diagram illustrating a positional relationship between a desirable measurement location on a surface of a housing and a thermistor in a smartphone according to Embodiment 3 of the present invention.

FIG. 6 is a flowchart illustrating an example of a method of determining a disposition location of the thermistor.

### DESCRIPTION OF EMBODIMENTS

### Embodiment 1

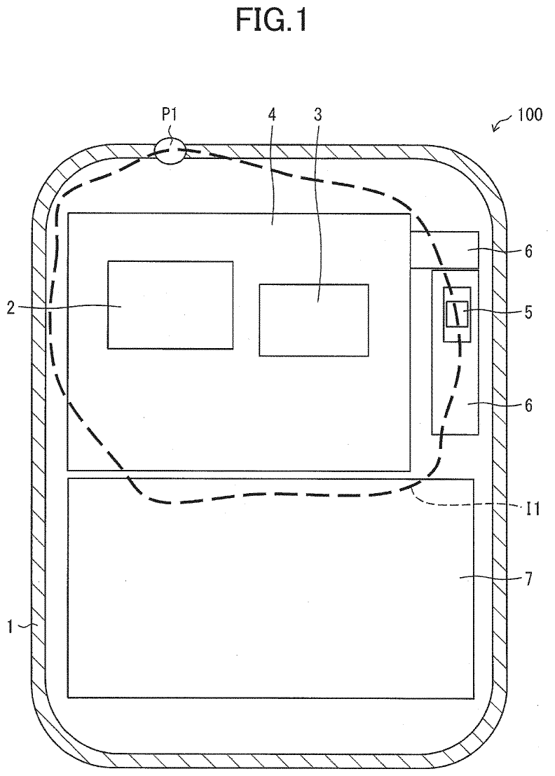

Hereinafter, embodiments of the present invention will be described in detail with reference to FIGS. 1 to 3. In each of the following embodiments relating the present embodiment, a smartphone will be described as an example of an electronic device according to one aspect of the present invention. However, various products such as a personal computer, a game machine, a tablet terminal, and a home appliance such as a refrigerator are used as the electronic device according to one aspect of the present invention in addition to the smartphone.

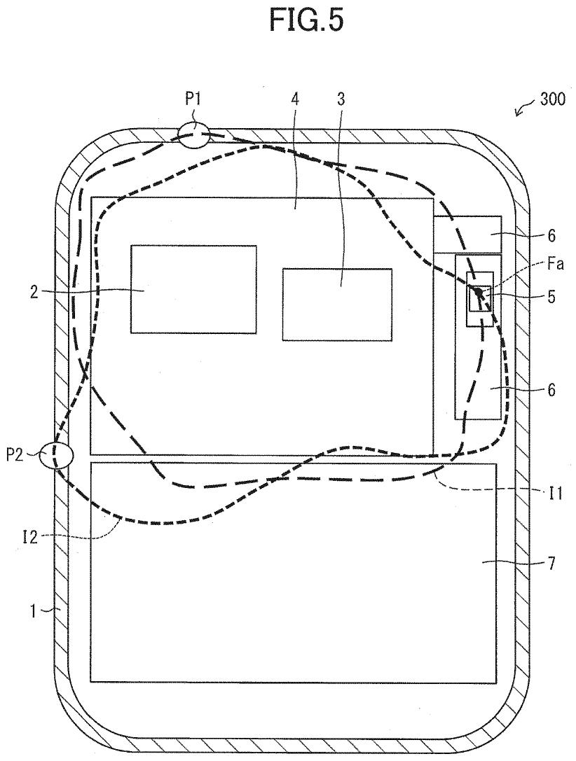

In the description of FIG. 1, for the sake of convenient description, it is assumed that an upper side of a page is an upper side, a lower side of the page is a lower side, a right side of the page is a right side, and a left side of the page is a left side. The same applies to description of FIGS. 4 and 5 which will be described below.

### <Disposition of Thermistor>

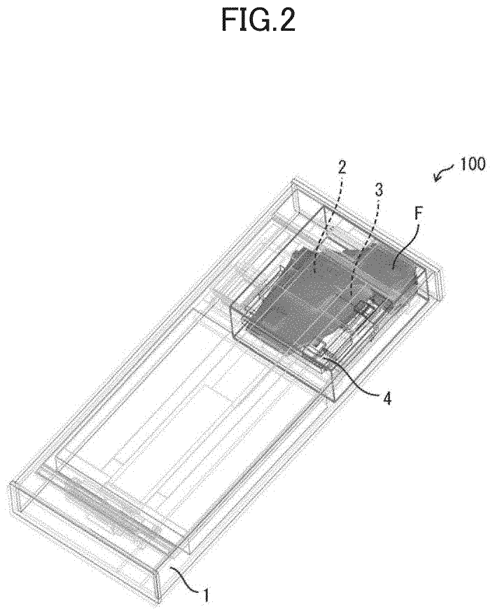

First, disposition of a thermistor 5 in the inside of a housing 1 of a smartphone 100 according to Embodiment 1 of the present invention will be described with reference to FIGS. 1 and 2. FIG. 1 is a schematic diagram illustrating a positional relationship between a desirable measurement location P1 on a surface of the housing 1 and the thermistor 5 in the smartphone 100. FIG. 2 is a schematic diagram illustrating another example of a temperature distribution in the inside of the housing 1.

The smartphone 100 (electronic device) is a multi-function mobile phone having functions of a personal computer and a PDA (Personal Digital Assistant). The same applies to smartphones 200 and 300 which will be described below. As illustrated in FIG. 1, a CPU 2 (electronic component), an IC chip 3 (electronic component), a board 4, a thermistor 5, a flexible printed board 6 (thermistor board), and a battery 7 are respectively arranged in the housing 1 of the smartphone 100.

The CPU 2 comprehensively controls an operation of each unit included in the smartphone 100 by executing a program stored in a memory (not illustrated) disposed in the inside of the IC chip 3 or the housing 1. The IC chip 3 is configured by connecting a large number of electronic elements such as a transistor, a capacitor, and a diode on a single board, and performs complicated processing and a large amount of data as a whole.

The CPU 2 and the IC chip 3 (electronic components) can serve as heat sources depending on a usage mode (hereinafter, abbreviated as a “usage mode”) of the smartphone 100 by the user, and presence/absence/degree of each heat generation changes depending on the usage mode. The CPU 2 and the IC chip 3 are mounted (disposed) on the rectangular board 4 in a planar view. The board 4 is disposed in an upper region in the inside of the housing 1, and for example, a rigid board and the like which are hard and are hard to bend are used.

The thermistor 5 measures a temperature of the inside of the housing 1 and is mounted (disposed) on the flexible printed board 6. The temperature measured by the thermistor 5 is estimated to be a temperature of a desirable measurement location P1 (desirable location; details will be described below) on a surface of the housing 1.

The flexible printed board 6 is a flexible board of an L shape in a planar view and is a base member on which a thin and soft insulating base film and a conductive metal such as a copper foil are bonded to each other and an electric circuit is formed. The flexible printed board 6 is disposed on the right side of the board 4 and is connected to the board 4. The battery 7 supplies power to each unit, various electronic components, and the like that configure the smartphone 100 including the CPU 2 and the IC chip 3, and is disposed below the board 4.

The board 4 on which the CPU 2 and the IC chip 3 serving as main heat sources are mounted tends to have a large temperature difference from a surface of the housing 1. There are many cases where a specific region having the same thermal resistance value as a thermal resistance value from the heat sources (CPU 2 and IC chip 3) to a desirable location on the surface of the housing is hard to be found on such the board 4.

Further, in a case where at least one of the CPU 2 and the IC chip 3 becomes the heat source depending on the usage mode, a temperature of the board 4 is higher than a temperature on the surface of the housing 1 by several tens of degrees C., and the board 4 becomes extremely high. If the thermistor 5 is mounted on the board 4 that can be in such a high temperature state, the thermistor 5 cannot measure the temperature of the inside of the housing 1 with a high accuracy depending on the usage mode. Therefore, by mounting the thermistor 5 on the flexible printed board 6 which is a member different from the board 4, it is possible to avoid a decrease in measurement accuracy due to an increase in the temperature of a mounting board.

However, the disposition location of the thermistor 5 in the housing 1 is not limited to the board 4 on which the CPU 2 or the like is mounted. The thermistor 5 demands to be disposed at a position in the housing 1 where a temperature that is the same or substantially the same as a maximum temperature of a desirable measurement location on the surface of the housing 1. That is, the thermistor 5 demands to be disposed on an isothermal line (isothermal region), in the inside of the housing 1, having the same thermal resistance value as a thermal resistance value from an electronic component in the housing 1 serving as a heat source to a desirable measurement location depending on the usage mode.

Here, the desirable measurement location indicates a specific location on the surface of the housing 1 where a user desires a temperature measurement depending on the usage mode, in other words, a location which is a target of the temperature measurement by the thermistor 5. In the present embodiment, the desirable measurement location P1 at which the temperature of the surface of the housing 1 is maximum in the first usage mode is the desirable measurement location.

Where the desirable measurement location P1 is on the surface of the housing 1 is mainly determined by a disposition of the electronic component serving as the heat source but is also affected by what environment the smartphone 100 is (for example, in a hot and humid state or the like). As another example of the desirable measurement location, for example, a specific location of the surface of the housing 1 which the longest finger of a user comes into contact with in the first usage mode can be used. In the present embodiment, the CPU 2 and the IC chip 3 serve as the heat sources in the first usage mode in which the temperature of the surface of the housing 1 is maximum at the desirable measurement location P1.

As another example of the electronic component in the housing 1 that can be the heat source, for example, a camera sensor (not illustrated), a backlight of an LCD (Liquid Crystal Display: see FIG. 4), an AC driver (not illustrated) can be used. In this case, for example, the camera sensor is disposed in a camera module (components other than the electronic component; not illustrated), and the backlight is disposed over the LCD (components other than the electronic component). Further, an LED can be used as another component in which the electronic component in the housing that can become the heat source is disposed. Furthermore, there is also a case where the electronic component that can be the heat source is one and there is also a case where the electronic component that can be the heat source is plural.

In a case where the CPU 2 and the IC chip 3 serve as the heat sources in the first usage mode, the desirable measurement location P1 exists at an end portion (end portion on an upper side) on a side closer to the board 4 of both end portions of the housing 1 in the short direction as illustrated in FIG. 1. Further, in the first usage mode, the CPU 2 generates more heat than the IC chip 3, and thus, the desirable measurement location P1 exists at a location directly above the CPU 2 at the end portion on the upper side.

In this case, an isothermal line I1 having the same thermal resistance value as a thermal resistance value from the CPU 2 and the IC chip 3 to the desirable measurement location P1 is formed to surround a periphery of the board 4 in a planar view as illustrated in FIG. 1. The isothermal line I1 is two-dimensionally formed on the same plane as the surface of the board 4 (the surface on which the CPU 2 and the IC chip 3 are mounted). Considering a formation state of the isothermal line I1 and a disposition of each component in the housing 1, any of (i) a left space of the board 4, (ii) an upper space of the board 4, and (iii) a right space of the board 4, and a location that can be disposed in the isothermal line I1 are candidates of the disposition location of the thermistor 5.

However, (i) the left space of the board 4 is narrow, and it is physically hard to dispose the thermistor 5. Next, (ii) the upper space of the board 4 is formed between the CPU 2 and the IC chip 3 that are heat sources and the desirable measurement location P1 where the temperature of the surface temperature of the housing 1 is maximized. Further, (ii) the upper space of the board 4 is formed in a region closer to the CPU 2 of the main heat source than (iii) the right space of the board 4. Therefore, if the thermistor 5 is disposed in (ii) the upper space of the board 4, the thermistor 5 is easily affected by a temperature rise of the heat source or the like.

Meanwhile, (iii) the right space of the board 4 is the widest of the three spaces and is formed in a region farthest from the main heat source CPU 2. Therefore, it is most preferable to dispose the thermistor 5 in (iii) the right space of the board 4 because the thermistor 5 is easily disposed and is hardly affected by the temperature rise of the heat source or the like. From the above, shape and disposition of the flexible printed board 6 are designed as described above such that the thermistor 5 can be disposed at (iii) the right space of the board 4 and on the isothermal line I1.

### Modification Example

The disposition/number of the thermistors 5 and the shape/disposition of the flexible printed board 6 are merely examples, and type/characteristics/disposition of an electronic component that can be a heat source in the inside of the housing 1 may be changed appropriately depending on a size of the space formed in the housing 1 or the usage mode.

Further, in the present embodiment, the disposition location of the thermistor 5 is first determined, and then a shape/disposition of the flexible printed board 6 is determined such that the thermistor 5 can be disposed at the determined location, but the present invention is not limited to this. For example, in a case where a large number of components are arranged inside the housing 1 and there is no space where the thermistor 5 can be separately disposed, the thermistor 5 cannot be disposed at a desirable location by using the flexible printed board 6 as described above.

In such a case, for example, some of components previously arranged in the housing 1 and different from the board 4 are selected. Further, from among the components, a component in which there is a space allowing the thermistor 5 to be disposed and the thermistor 5 can be disposed in the isothermal line I1 is selected, and the thermistor 5 may be finally disposed on the selected component. In other words, the thermistor 5 may be disposed on any component (thermistor board) in the housing 1 which is a member different from the board 4.

It is needless to say that the finally selected component can be used as a heat source depending on the usage mode, or a component for generating heat by itself is excluded.

Further, the fact is not limited that an isothermal region having the same thermal resistance value as the heat resistance value from the electronic component in the housing 1 serving as a heat source to the desirable measurement location is two-dimensionally formed in the same manner as the isothermal line I1. For example, as illustrated in FIG. 2, there is also a case where the isothermal region F is three-dimensionally formed to cover the CPU 2 and the IC chip 3 serving as a heat source, and components and the like around the CPU 2 and the IC chip 3. In such a case, if a portion formed in (iii) the right space of the board 4 in the isothermal region F is not on the same plane as the surface of the board 4, the thermistor 5 may be disposed in the above-described portion by appropriately deforming the flexible printed board 6.

As such, in the flexible printed board 6, the thermistor 5 can be easily disposed in the isothermal region regardless of a form of the isothermal region, but the flexible printed board 6 is not necessarily used. For example, a hard vinyl film or the like may be used in place of the flexible printed board 6, and any member may be used as long as the member is flexible.

### <Method of Determining Disposition Location of Thermistor>

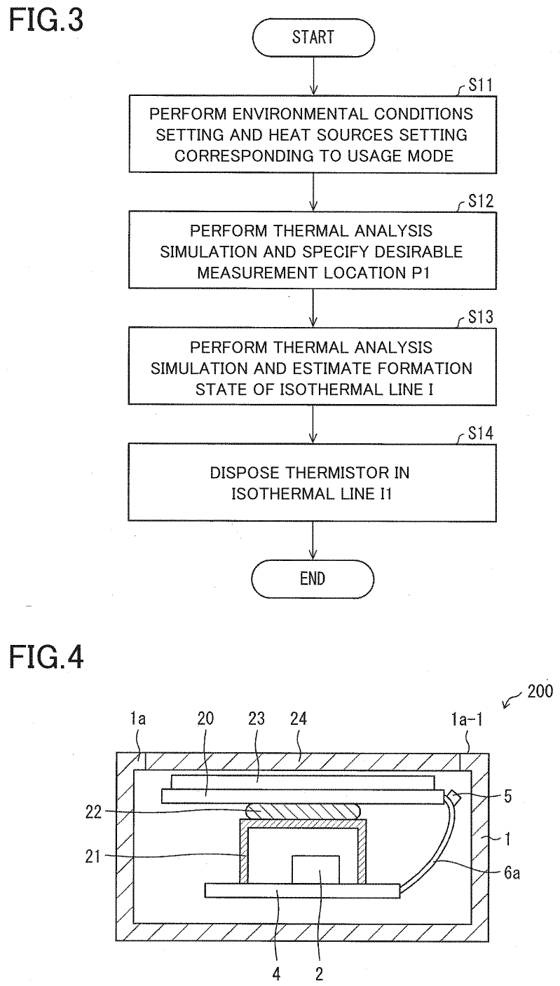

Next, a method of determining the disposition location of the thermistor 5 will be described with reference to FIG. 3. FIG. 3 is a flowchart illustrating an example of the method of determining the disposition location of the thermistor 5.

In order to determine the disposition location of the thermistor 5, it is demanded to specify an electronic component that is a heat source and a desirable measurement location as described above, and to estimate what an isothermal region is formed. In the present embodiment, it is assumed that the processing is performed by a thermal analysis simulation. Specifically, the thermistor 5 can be disposed in the isothermal line I1 by performing each step (hereinafter, abbreviated as “S”) of step 11 to step 13 by using the thermal analysis simulation.

As illustrated in FIG. 3, a user first operates an operation input unit of an information processing device (not illustrated) in which software related to the thermal analysis simulation is installed, and inputs various types of information of the CPU 2 and IC chip 3 serving as heat sources. For example, power consumption and physical property values (thermal conductivity, specific heat, density, emissivity, and the like) of each of the CPU 2 and the IC chip 3, a disposition location in the housing 1, and the like are input as the various types of information. Likewise, a usage mode and environmental conditions (such as temperature and humidity) of the smartphone 100 are set (S11).

Next, the information processing device performs the thermal analysis simulation, and specifies the desirable measurement location P1 based on the various types of information of the CPU 2 and IC chip 3, the usage mode of the smartphone 100, and the environmental conditions (S12). Then, the thermal analysis simulation is also performed to determine the isothermal line I1 in the housing 1 that has the same thermal resistance value as the thermal resistance value from the CPU 2 and IC chip 3 to the desirable measurement location P1, and it is estimated how the isothermal line I1 is formed (S13).

Next, the information processing device selects a space in the housing 1 where the thermistor 5 can be disposed in the isothermal line I1 estimated by the thermal analysis simulation ((iii) the right space of the board 4; see FIG. 1), and disposes the thermistor 5 on the isothermal line I1 by using the flexible printed board 6 (S14).

### Embodiment 2

Another embodiment of the present invention will be described with reference to FIG. 4 as follows. For the sake of convenient description, a member having the same functions as the member described in the above-described embodiment is denoted by the same reference numeral, and description thereof will be omitted. A point that a desirable measurement location becomes the desirable measurement location P1, a point that the CPU 2 and the IC chip 3 become the heat sources, and the point that the CPU 2 becomes a main heat source are the same as in Embodiment 1.

### <Disposition of Thermistor>

Disposition of the thermistor 5 in the inside of the housing 1 of the smartphone 200 according to Embodiment 2 of the present invention will be described with reference to FIG. 4. FIG. 4 is a schematic diagram illustrating an internal structure of the housing 1 in the smartphone 200.

As illustrated in FIG. 4, two members slightly larger than the board 4, that is, a metal plate 20 (heat conducting member) and a graphite sheet 23 (heat conducting member) are disposed above the CPU 2 and the IC chip 3 (the IC chip 3 is not illustrated in FIG. 4) in the inside of the housing 1 of the smartphone 200.

Specifically, the CPU 2 and IC chip 3 are covered by a shield 21 disposed on the board 4, and the metal plate 20 is fixed to an upper surface of the shield 21 via a gasket 22. A plate-shaped graphite sheet 23 is attached to an upper surface of the metal plate 20, and an upper surface of the graphite sheet 23 faces an LCD 24 buried in an upper wall 1a of the housing 1. The metal plate 20 is preferably formed of a metal having a high thermal conductivity. Further, the graphite sheet 23 is a member having a high thermal conductivity. A configuration in which any one of the metal plate 20 and the graphite sheet 23 is disposed may be provided.

The board 4 and the metal plate 20 are connected to each other by a flexible printed board 6a (thermistor board). The flexible printed board 6a was originally flat and is bent to be able to connect the board 4 to the metal plate 20. The thermistor 5 is mounted on a portion near a connection location with the metal plate 20 in the flexible printed board 6a.

The metal plate 20 and the graphite sheet 23 function to reduce a temperature gradient from the CPU 2 and IC chip 3 serving as heat sources to a surface 1a-1 of an upper wall 1a of the housing 1. Therefore, by disposing the metal plate 20 and the graphite sheet 23 inside the housing 1, the isothermal line I1 having the same thermal resistance value as the thermal resistance value from the CPU 2 and IC chip 3 to the desirable measurement location P1 is easily generated near the metal plate 20 and the graphite sheet 23. Specifically, the isothermal line I1 is two-dimensionally formed on a plane substantially the same as an upper surface of the metal plate 20 (not illustrated in FIG. 4).

Further, since the thermistor 5 is disposed near the metal plate 20 and the graphite sheet 23 and at substantially the same height as a height from a lower surface of a lower wall 1b to an upper surface of the metal plate 20 of the housing 1, the thermistor 5 is reliably disposed in the isothermal line I1.

Thereby, it is possible to measure a temperature of the desirable measurement location P1 with a higher accuracy by simply disposing at least one thermistor at an appropriate position on the flexible printed board 6a. Instead of the metal plate 20, another member with a high thermal conductivity may be connected to the board 4 by the flexible printed board 6a. In other words, any member that reduces the temperature gradient from the CPU 2 and IC chip 3 to any surface of the housing 1 may be connected to the board 4 by the flexible printed board 6a.

Further, it is not fundamental that the board 4 is connected to the metal plate 20 by the flexible printed board 6a. Since the thermistor 5 may be reliably disposed in the isothermal line I1, the flexible printed board 6a may be in contact with the metal plate 20 or may be disposed near the metal plate 20 at a minimum. Alternatively, the flexible printed board 6a may be in contact with the graphite sheet 23 or may be disposed near the graphite sheet 23. Furthermore, the shield 21 may be configured to perform a function of the metal plate 20.

### Embodiment 3

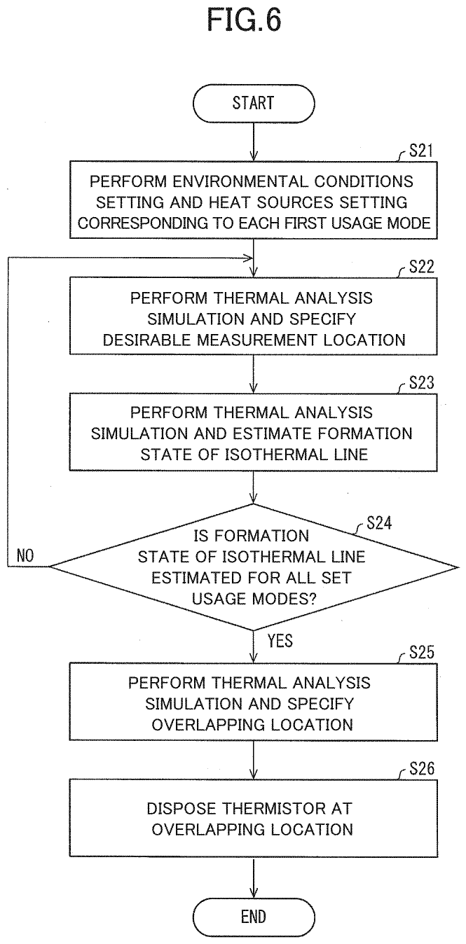

Another embodiment of the present invention will be described with reference to FIG. 5 and FIG. 6 as follows. For the sake of convenient description, a member having the same functions as the member described in the above-described embodiment are denoted by the same reference numeral, and descriptions thereof will be omitted. A point that the CPU 2 and the IC chip 3 become heat sources is the same as in the first embodiment.

### <Disposition of Thermistor>

Disposition of the thermistor 5 in the inside of the housing 1 of the smartphone 300 according to Embodiment 3 of the present invention will be described with reference to FIG. 5. FIG. 5 is a schematic diagram illustrating a positional relationship between the desirable measurement locations P1 and P2 on a surface of the housing 1 and the thermistor 5, in the smartphone 300.

In a case where a second usage mode exists in addition to the first usage mode, the smartphone 300 is devised to dispose the thermistor 5 such that a temperature of the surface of the housing 1 in each usage mode can be accurately measured. Points other than this are the same as the points of the smartphone 100 according to Embodiment 1.

A desirable measurement location in this case is two locations of the desirable measurement location P1 and the desirable measurement location P2 where the temperature of the surface of the housing 1 becomes maximum in the second usage mode. That is, a plurality of desirable measurement locations exist on the surface of the housing 1 depending on the usage mode.

In the present embodiment, also in the second usage mode, the CPU 2 and the IC chip 3 serve as heat sources in the same manner as in the first usage mode, and the CPU 2 generates more heat than the IC chip 3. Meanwhile, a ratio of the heat generation amount of the IC chip 3 to the heat generation amount of the CPU 2 is different from a ratio in the first usage mode. Therefore, as illustrated in FIG. 5, the desirable measurement location P2 exists near the center of an end portion (end portion on the right side) on a side close to the board 4 among both end portions in the longitudinal direction of the housing 1.

In this case, an isothermal line I2 having the same thermal resistance value as the thermal resistance value from the CPU 2 and the IC chip 3 to the desirable measurement location P2 is formed to surround a periphery of the board 4 in a planar view as illustrated in FIG. 5. Further, the isothermal line I2 is two-dimensionally formed on the same plane as a surface of the board 4.

As described above, in a case where two isothermal lines (isothermal lines I1 and I2) exist inside the housing 1, if one thermistor 5 performs a temperature measurement with a high accuracy, it is most preferable to dispose the thermistor 5 at an overlapping location where the isothermal line I1 and the isothermal line I2 overlap each other.

In the present embodiment, a case where there are two types of usage modes is described as an example, but the thermistor 5 may be disposed by using the same method as described above even in a case where there are three or more types of usage modes. That is, in a case where there are a plurality of isothermal lines or isothermal regions in the inside of the housing 1 depending on the usage mode, the thermistors may be arranged at overlapping locations where all of the plurality of isothermal lines or the plurality of isothermal regions overlap each other.

### <Method of Determining Disposition Location of Thermistor>

Next, a method of determining disposition location of the thermistor 5 will be described with reference to FIG. 6. FIG. 6 is a flowchart illustrating an example of the method of determining the disposition location of the thermistor 5. A point that software related to a thermal analysis simulation is installed in an information processing device and a point that an isothermal region is determined by the thermal analysis simulation are the same as in the first embodiment.

As illustrated in FIG. 6, a user first operates an operation input unit of the information processing device to input various types of information of the CPU 2 and IC chip 3 serving as heat sources and sets an environmental condition of the smartphone 300. Further, the first usage mode and the second usage mode are set (S21).

Next, the information processing device performs the thermal analysis simulation, and specifies the desirable measurement location P1 based on various types of information of the CPU 2 and IC chip 3, the first usage mode, and the environmental condition (S22). Then, the thermal analysis simulation is performed in the same manner to determine the isothermal line I1 in the housing 1 that has the same thermal resistance value as the thermal resistance value from the CPU 2 and IC chip 3 to the desirable measurement location P1, and it is estimated how the isothermal line I1 is formed (S23).

Next, the information processing device determines whether or not how the isothermal line is formed is estimated for all the set usage modes (S24). In a case where it is determined to be NO in S24, the information processing device performs various types of processing of S22 and S23 again. In the processing of S23, since only the isothermal line I1 corresponding to the first usage mode is not estimated, the information processing device performs each processing of S22 and S23 again.

In the processing of S23, the isothermal line I2 in the housing 1 having the same thermal resistance value as the thermal resistance value from the CPU 2 and IC chip 3 to the desirable measurement location P2 is determined, and if how the isothermal line I2 is formed is estimated, the information processing device determines YES in S24.

In a case where it is determined YES in S24, the information processing device specifies an overlapping location Fa from the isothermal lines I1 and I2 estimated by performing the thermal analysis simulation (S25). Then, a space in the housing 1 in which the thermistor 5 can be disposed at the overlapping location Fa is selected ((iii) right space of the board 4; see FIG. 5), and the thermistor 5 is disposed at the overlapping location Fa by using the flexible printed board 6 (S26).

### SUMMARY

According to an electronic device (smartphones 100, 200, 300) according to a first aspect of the present invention, the electronic device in which an electronic component (CPU2, IC chip 3) capable of being a heat source depending on a usage mode is disposed on a board (4) or on a component other than the electronic component in a housing (1), includes a thermistor (5) that measures a temperature of an inside of the housing, in which the thermistor is disposed on a thermistor board (flexible printed board 6, 6a) that is a member different from the board or the component on which the electronic component is disposed.

A board on which an electronic component serving as a main heat source is disposed tends to have a large temperature difference from a surface of a housing. Particularly, the tendency is noticeable in an electronic device having the large amount of CPU processing such as a smartphone. There are many cases where a specific region having the same thermal resistance value as a thermal resistance value from the heat source (one or two or more electronic components) to a desirable location on the surface of the housing cannot be found on such a board.

In that respect, according to the above-described configuration, since a thermistor is disposed on a thermistor board different from a board on which an electronic component is disposed or a component on which the electronic component is disposed, a degree of freedom of a disposition location in the housing of the thermistor is increased depending on a design of the thermistor board.

Therefore, in a case where a temperature of a desirable location on the surface of the housing is desired to be measured, the thermistor board can be designed such that the thermistor can be disposed at a specific region in the housing having the same thermal resistance value as the thermal resistance value from the heat source (one or two or more electronic components) to the desirable location. Further, in a case where there are a plurality of the desirable locations, a location where all of the specific regions corresponding to each of the plurality of desirable locations overlap is determined, and the thermistor board can be designed such that the thermistor can be disposed at the overlapping location.

Therefore, it is not demanded to dispose the thermistors at a plurality of locations in the housing in order to measure a temperature at a desirable location on the surface of the housing, and the temperature at the desirable location can be measured with a high accuracy only by disposing at least one thermistor on the thermistor board. Further, even in a case where there are a plurality of the desirable locations, it is possible to the temperature with a high accuracy for each of the plurality of desirable locations by simply disposing at least one thermistor on the thermistor board.

According to an electronic device according to a second aspect of the present invention, in the first aspect, the thermistor board may have flexibility.

There is a case where a specific region having the same thermal resistance value as a thermal resistance value from a heat source (one or two or more electronic components) to a desirable location on a surface of a housing exists three-dimensionally in the housing. In such a case, it is demanded to deform a thermistor board in order to dispose a thermistor in a specific region depending on a disposition position of the thermistor board.

In that respect, according to the above-described configuration, since the thermistor board has flexibility, even if the specific region exists three-dimensionally, the thermistor board can be appropriately deformed to easily dispose the thermistor at a specific region. Therefore, only by disposing at least one thermistor on the thermistor board, it is possible to measure a temperature at a desirable location on a surface of a housing with a high accuracy regardless of an existence state of the specific region.

According to an electronic device (smartphone 200) according to a third aspect of the present invention, in the first or second aspect, a heat conducting member (metal plate 20, graphite sheet 23) may be disposed inside the housing to reduce a temperature gradient from the electronic component serving as a heat source to a surface of the housing, and the thermistor board (flexible printed board 6a) may be in contact with the heat conducting member or may be disposed near the heat conducting member.

According to the above-described configuration, since a heat conducting member with a high thermal conductivity is disposed inside a housing, it is possible to close to a temperature of a surface of the housing by thermally diffusing heat of a heat source using the heat conducting member.

By doing so, a temperature difference between the surface of the housing and the heat conducting member can be reduced and a temperature gradient can be reduced, and thus, during this time, a location having the same temperature as a desirable temperature of the surface of the housing can be easily provided in the housing. Further, allowing a heat dissipation path from a heat source to the surface of the housing to be wide, not local, by using the heat conducting member becomes an element that can easily provide the inside of the housing with the location having the same temperature as the desirable temperature of the surface of the housing.

Therefore, a specific region having the same thermal resistance value as a thermal resistance value from the heat source (one or two or more electronic components) to a desirable location on surface of the housing is easily generated near the heat conducting member. Further, since the thermistor board is in contact with the heat conducting member or is disposed near the heat conducting member, it is possible to reliably dispose a thermistor in the specific region by disposing the thermistor on the thermistor board.

Therefore, only by disposing at least one thermistor on the thermistor board, it is possible to measure a temperature of a desirable location on the surface of the housing with a higher accuracy.

According to an electronic device (smartphone 300) according to a fourth aspect of the present invention, in any one of the first to third aspect, a plurality of desirable locations (desirable measurement locations P1 and P2) that are targets of temperature measurement by the thermistor may exist on a surface of the housing depending on the usage mode of the electronic device, a plurality of isothermal regions (isothermal lines I1 and I2) having the same thermal resistance value as a thermal resistance value from the electronic component serving as a heat source to the desirable location may exist inside the housing depending on the usage mode of the electronic device, and the thermistor is disposed in an overlapping location (Fa) where all of the plurality of isothermal regions overlap each other.

According to the above-described configuration, a thermistor is disposed at an overlapping location. Thus, even in a case where a temperature distribution near an electronic component varies depending on a usage mode of an electronic device (in a case where there are a plurality of isothermal regions inside the housing), the thermistor can measure substantially the same temperature as a temperature of at least the location for each of the plurality of desirable locations.

Therefore, after the thermistor board is provided such that the thermistor is disposed at the overlapping location, by disposing at least one thermistor on the thermistor board, it is possible to measure a temperature of the location with a high accuracy for each of the plurality of desirable locations.

The present invention is not limited to the respective embodiments described above, various modifications are possible within the scope described in the claims, and embodiments obtained by appropriately combining technical means disclosed in different embodiments are also included in the technical scope of the present invention.

Furthermore, a new technical feature can be formed by combining the technical means disclosed in the respective embodiments.

### REFERENCE SIGNS LIST

1 HOUSING
1a-1 SURFACE
2 CPU (ELECTRONIC COMPONENT)
3 IC CHIP (ELECTRONIC COMPONENT)
4 BOARD
5 THERMISTOR
6,6a FLEXIBLE PRINTED BOARD (THERMISTOR BOARD)
20 METAL PLATE (HEAT CONDUCTING MEMBER)
23 GRAPHITE SHEET (HEAT CONDUCTING MEMBER)
100,200,300 SMARTPHONE (ELECTRONIC DEVICE)
F ISOTHERMAL REGION
Fa OVERLAPPING LOCATION
I1,I2 ISOTHERMAL LINE (ISOTHERMAL REGION)
P1,P2 DESIRABLE MEASUREMENT LOCATION (DESIRABLE LOCATION)

1. An electronic device in which an electronic component capable of being a heat source depending on a usage mode is disposed on a board or on a component other than the electronic component in a housing, comprising:
a thermistor that measures a temperature of an inside of the housing,
wherein the thermistor is disposed on a thermistor board that is a member different from the board or the component on which the electronic component is disposed.

2. The electronic device according to claim 1, wherein the thermistor board has flexibility.

3. The electronic device according to claim 1,
wherein a heat conducting member is disposed inside the housing to reduce a temperature gradient from the electronic component serving as a heat source to a surface of the housing, and
wherein the thermistor board is in contact with the heat conducting member or is disposed near the heat conducting member.

4. The electronic device according to claim 1,
wherein a plurality of desirable locations that are targets of temperature measurement by the thermistor exist on a surface of the housing depending on the usage mode of the electronic device,
wherein a plurality of isothermal regions having the same thermal resistance value as a thermal resistance value from the electronic component serving as a heat source to the desirable location exist inside the housing depending on the usage mode of the electronic device, and
wherein the thermistor is disposed in an overlapping location where all of the plurality of isothermal regions overlap each other.
